(19) United States
(12) Patent Application Publication
(10) Pub. No.: US 2002/0137366 A1
(43) Pub. Date: Sep. 26, 2002

(54) Universal low profile connector for grid arrays with organic contact retainer

(76) Inventors: Yakov Belopolsky, Harrisburg, PA (US); Dale Hollenbaugh, Elizabethtown, PA (US)

Correspondence Address: David L. Marcus, Esq., Woodcock Washburn Kurtz, Mackiewicz & Norris LLP, One Liberty Place - 46th Floor, Philadelphia, PA, 19103, US

(21) Appl. No.: 09/817,159

(22) Filed: Mar. 26, 2001

(51) Int. Cl. H05K 1/00

(52) U.S. Cl. 439/71

(57) ABSTRACT

An electrical connector connects an electric component having a grid array of electrical contacts. The connector comprises a connector base, a plurality of contact pads attached to a surface of the connector base, a plurality of lotus spring contacts attached to a corresponding contact pad in the grid array, and an organic film through which each of the lotus spring contacts protrudes. The organic film provides structural integrity and ease of handling during assembly and subsequent use of the connector. A method of mounting a connector to an electrical component having a grid array of electrical contacts on a surface thereof. The method comprises positioning the electrical component in close proximity to the connector so that each of a plurality of lotus spring contacts on the connector touch a corresponding contact in the grid array of electrical contacts on the connector. The method further comprises applying a force to the electrical component so that each of the lotus spring contacts on the connector engages the corresponding contact in the grid array of contacts on the electrical component.

### I. BACKGROUND

A. Field of the Invention

This invention relates generally to the field of electrical connectors, and particularly to universal array connectors for joining a connector base to a land or ball grid array of electrical contacts and methods of using the same.

B. Description of the Related Art

As processer speeds increase, lower signal inductances are required to handle the speed of the various signals sent and received by the processor. Lower signal line inductances in turn require connectors of smaller and smaller dimensions. In addition, connectors of smaller and smaller dimensions are needed so that computers and mobile telecommunications equipment can be made smaller and lighter. At the same time, end users of the products want the ability to easily upgrade the processors in their equipment. This requires connectors that will accept microprocessors produced by different suppliers in a wide variety of packages (e.g., very large scale integrated circuit (VLSI) packages with either land grid array (LGA) or ball grid array (BGA) electrical contacts) and that will withstand multiple insertion events.

However, designing and building connectors having such properties as very low inductance, low profile, high density connections, the ability to accommodate a wide variety of packages, and the ability to withstand multiple insertions poses several problems. In general, there are three ways to lower the inductance of a connector. One can reduce the length of the signal path. One can increase the thickness of the electrical conductor. And finally, one can provide parallel signal paths. Utilizing the first and final methods of reducing inductance results in a connector with a large number and high density of contacts, but the contacts are very short and fragile. The connectors are therefore difficult to handle during the manufacturing process and susceptible to damage during insertion events.

The present invention solves these problems by providing a universal, low profile, low inductance connector with a large number of contacts that have a high structural integrity that is beneficial for handling in the manufacturing process and has the ability to withstand multiple insertion events.

### II. SUMMARY OF THE INVENTION

An electrical connector comprising: a plurality of lotus spring contacts, each lotus spring contact having at least two beams, each beam having a base and distal end, the beams of each lotus spring contact being joined at the base ends thereof to form a base for being connected to a connector base, the beams of each lotus spring contact defining a recess at the distal ends thereof for receiving a corresponding contact of a grid array; and a generally planar organic film oriented substantially perpendicular to the plurality of lotus spring contacts such that the lotus spring contacts protrude therethrough; wherein the organic film provides structural integrity to the beams of the lotus spring contacts.

A method of assembling an electrical connector comprising: forming a plurality of lotus spring contacts, each lotus spring contact having at least two beams, each beam having a base and distal end, the beams of each lotus spring contact being joined at the base ends thereof to form a base, the beams of each lotus spring defining a recess at the distal ends thereof; positioning the lotus spring contacts in a grid array; forming an organic film around the lotus spring contacts; forming a meniscus of liquid solder between the beams of each of the lotus spring contacts adjacent the base ends thereof; allowing each of the meniscus of liquid solder to solidify; positioning the base of each of the lotus spring contacts adjacent to and touching a corresponding contact pad on a surface of a connector base; heating the connector base so that each of the meniscus of solder liquify and a portion thereof runs onto the corresponding contact pad; allowing each meniscus of solder and each portion thereof on the corresponding contact pad to solidify.

A method of using an electrical connector, the electrical connector comprising a connector base mechanically and electrically connected to a plurality of lotus spring contacts, each of the lotus spring contacts having a plurality of beams, the beams having a base and distal end, the distal ends of each lotus spring contact defining a recess for receiving a corresponding electrical contact on an electrical component, and a generally planar organic film oriented substantially perpendicular to the lotus spring contacts such that each of the lotus spring contacts protrude therethrough, comprising: positioning the electrical component so that the curved recess of each lotus spring contact touches the corresponding electrical contact on the electrical component; and applying a force generally normally to the component and connector base so that each of the lotus spring contacts engage the corresponding electrical contact on the component.

### III. BRIEF DESCRIPTION OF THE DRAWINGS

These and other features, aspects, and advantages of the present invention will become better understood with regards to the following description, appended claims, and accompanying drawings where:

FIG. 1 is a side view of one embodiment of the present invention with the contacts engaging a ball grid array on an electrical component;

FIG. 2 is a side view of one embodiment of the present invention with the contacts engaging a land grid array on an electrical component:

FIG. 3 is a perspective view of the embodiment of the present invention and electrical component depicted in FIG. 1;

FIG. 4 is a perspective view of a heat sink about to be attached to the embodiments of the invention depicted in FIGS. 1-3;

FIG. 5 is a perspective view of the underside of the heat sink depicted in FIG. 4;

FIG. 6 is a flow diagram of a method of assembling one embodiment of the present invention; and

FIG. 7 is a flow diagram of a method for connecting an electrical component to one embodiment of the present invention.

### IV. DETAILED DESCRIPTION OF THE PREFERRED EMBODIMENTS

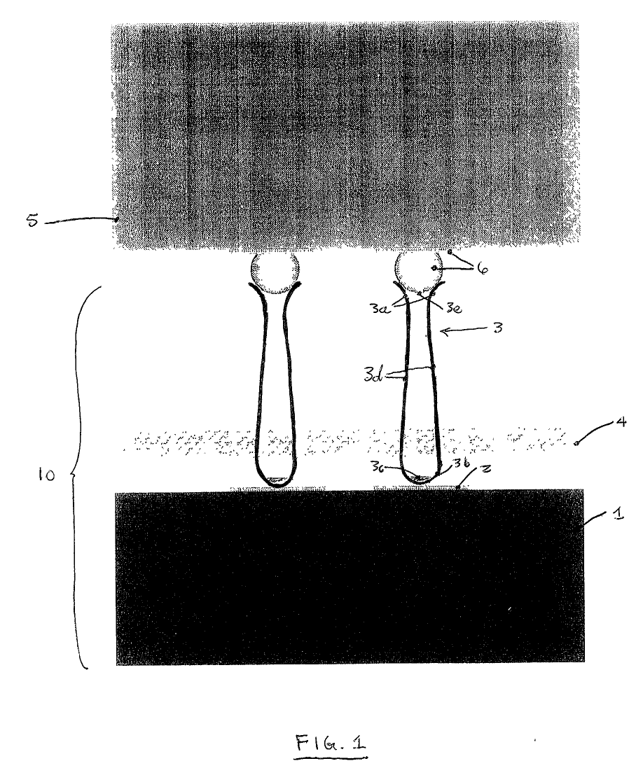

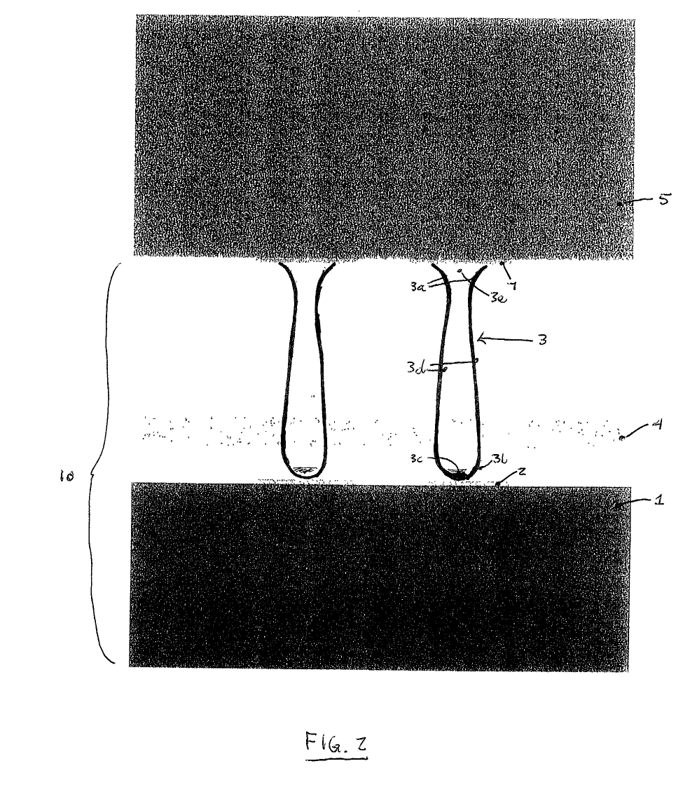

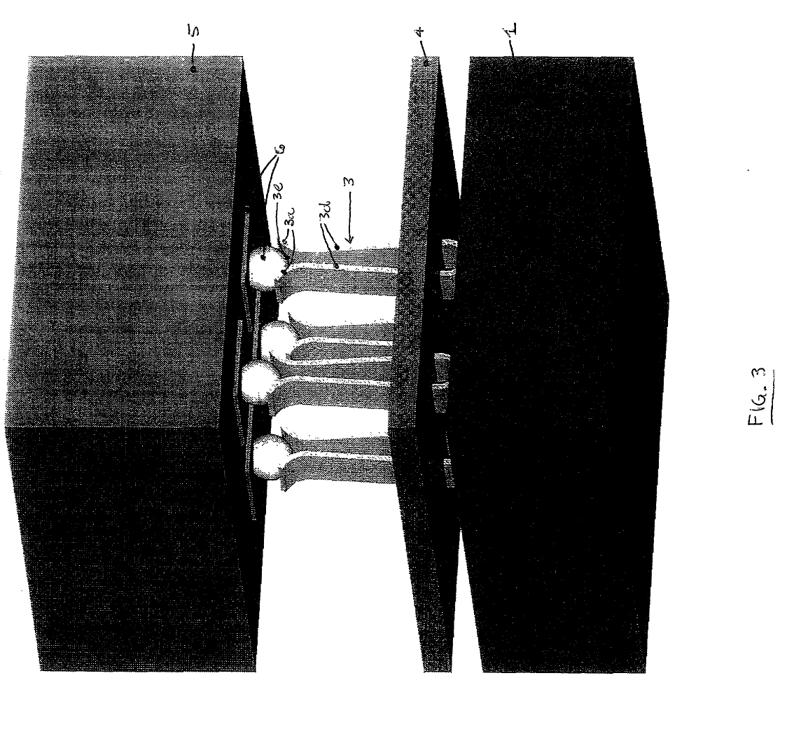

Throughout the following detailed description similar reference numbers refer to similar elements in all the figures of the drawings. Referring now to FIGS. 1 and 2, side views of an embodiment of the present invention with the petals 3a of lotus spring contacts 3 engaging a BGA of electrical contacts 6 (FIG. 1) and a LGA of electrical contacts 7 (FIG. 2) on an electric component 5. Electrical component 5 can be any electrical component having a LGA or BGA of electrical contacts on one side thereof, such as a VLSI or even a heat sink. As seen in FIGS. 1-3, connector 10 comprises a connector base 1, conductive pads 2, a plurality of the lotus springs 3, and organic film 4. Connector base 1, sometimes referred to as a socket, is comprised of an electrically nonconductive material such as alumina, epoxy resin, boron nitride, aluminum nitride, or the like. Attached to the top surface of connector base 1 are contact pads 2. Contact pads 2 typically comprise copper covered with solder and convey electrical signals between lotus spring contacts 3 and an electrical component such as a printed wire board or motherboard (not shown) electrically connected to the bottom surface of connector base 1.

Attached to the top of each contact pad 2, typically by a solder joint, is a lotus spring contact 3. Lotus spring contact 3 is an electrical contact comprising a base 3b, a plurality of beams 3d emanating from base 3b that are roughly parallel to any opposing beam 3d emanating from base 3b that define a volume of space between each other that acts as a capillary in the presence of liquid solder, and petals 3a that form a curved recess 3e for receiving or engaging the solder ball contacts 6 of the BGA in FIG. 1 or the flat electrical contacts 7 of the LGA in FIG. 2. In this embodiment of the invention, beams are opposing when their vertical centerlines are located roughly 180 degrees around the curved recess formed by petals 3a from each other. In one embodiment of the invention lotus spring contacts 3 are formed from a high thermally and electrically conductive metal. For example, lotus spring contacts 3 may be formed from nickel and finished with gold. As seen, lotus spring contacts 3 protrude through organic film 4 which is generally parallel to the top surface of connector base 1.

Organic film 4 may comprise either a permanently retained organic film or a temporarily retained organic film. In either case however, organic film 4 provides additional structural integrity or support to lotus spring contacts 3 during assembly and subsequent use of connector 10 by resisting any motion tending to open or enlarge the curved recess 3e formed by petals 3a. The presence of organic film 4 also provides a convenient mode of handling lotus spring contacts 3 during the assembly and subsequent use of connector 10. In embodiments of the invention employing a permanently retained organic film, organic film 4 remains in place after connector 10 has been used to form a connection between electric component 5 and a second electrical component such as a printed circuit, mother board or heat sink (not shown) in electrical and/or thermal communication with a bottom surface of connector base 1. In one embodiment of the invention the permanently retained organic film is KAPTON, a polyimide film manufactured and sold by E.I. du Pont de Nemours and Company of Wilmington, Del., that is approximately 0.001 inches thick. In embodiments of the invention employing a temporarily retained organic film, organic film 4 is removed after connector 10 has been used to form the aforementioned connection between electric component 5 and the second electrical component. In one embodiment of the invention, the temporarily retained organic film is comprised of gelatin deposited on a thin polymer film. Typical polymer films that may be used are polyimide or polyester films. The invention is not however limited to the use of a pre-formed organic film and contemplates the formation of a film around the lotus spring contacts.

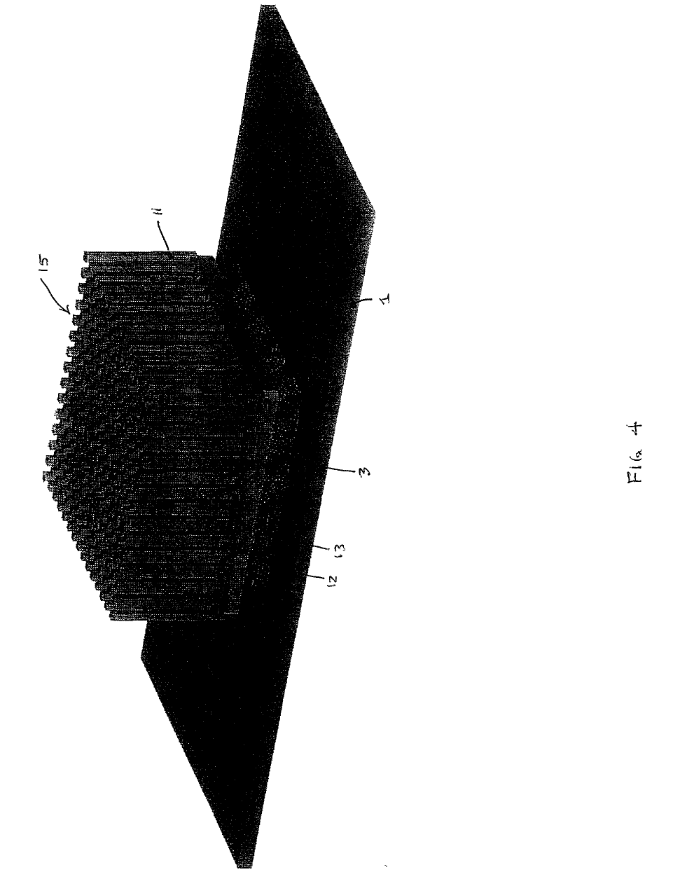

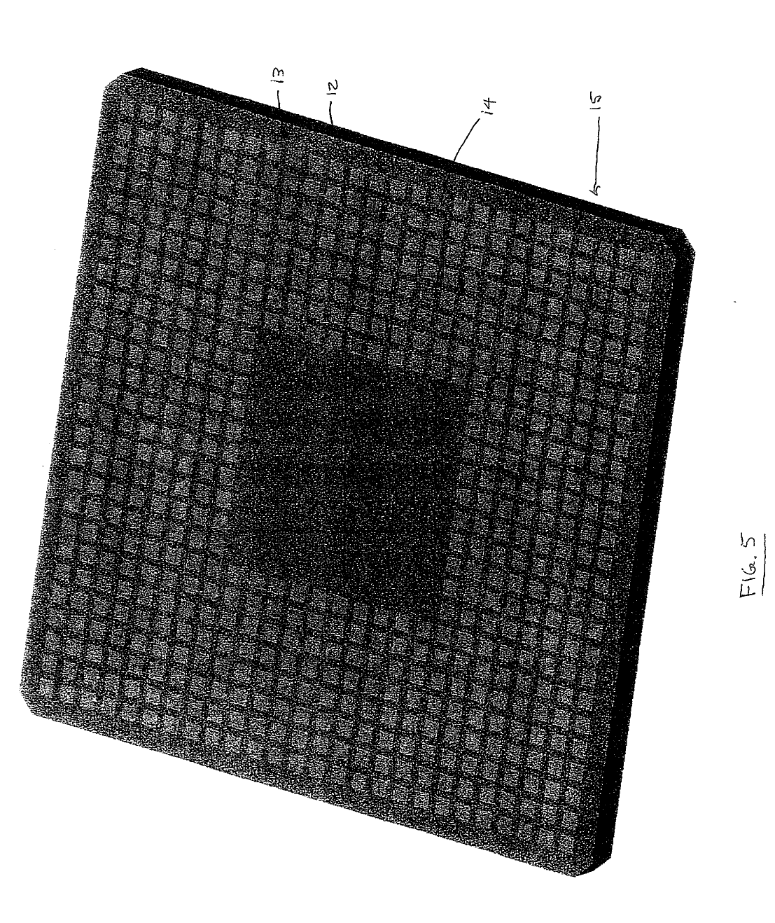

Referring now to FIG. 4, a perspective view is shown of a heat sink 15 that may be attached to an embodiment of connector 10 by lotus spring contacts 3. FIG. 5 shows a perspective view of the underside of heat sink 15. In the embodiment of the invention depicted in FIGS. 4 and 5, heat sink 15 is comprised of three elements, a plurality of high thermal conductivity metal fins joined by a base 11, an electrical insulator 12 in immediate contact with the base 11 of the metal fins, and a plurality of contact pads 14 in a LGA pattern attached to a side of the electrical insulator 12 not in contact with the base of the metal fins 11. The electrical insulator 12 may comprise any number of materials, including materials such as polyimide and/or polyester or the like. Contact pads 14 may comprise any number of materials as well, including materials such as gold, molybdenum, and/or tungsten or the like. Heat sink 15 would then be positioned so that the curved recess 3e at the open end of each of the locus spring contacts 3 touch a corresponding contact pad 14 attached to electrical insulator 13. Finally, a force would be applied generally normal to heat sink 15 and connector base 1 so that each of the lotus spring contacts 3 engage the corresponding contact pad 14 on heat sink 15, thereby creating both a physical and thermal connection between connector 10 and heat sink 11.

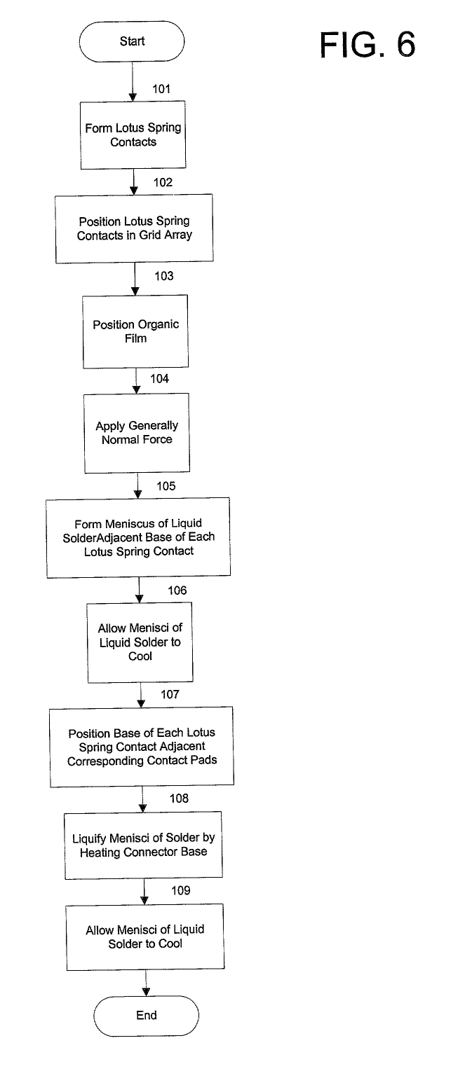

Referring now to FIG. 6, a flow diagram of a method of assembling connector 10 is depicted. In step 101 the plurality of lotus spring contacts 3 are formed. In step 102, the lotus spring contacts are positioned in a grid array through the use of a jig or the like. In step 103, organic film 4 is positioned parallel to the top surface of connector base 1 just above petals 3a of the lotus spring contacts 3. In step 104, a force is applied generally normally to the lotus spring contacts 3 and organic film 4 so that the petals 3a and beams 3d of the lotus spring contacts 3 first pierce and then protrude through organic film 4. In step 105, the base 3b of each lotus contact 3 is either dipped in liquid solder or wave soldered, which results in a small meniscus of liquid solder 3c being retained within the volume of space formed by the beams 3d of lotus spring contacts 3 immediately adjacent bases 3b of lotus spring contacts 3. In step 106, the small menisci of liquid solder 3c are allowed to cool and thereby solidify. In step 107, the bases 3b of the plurality of lotus spring contacts 3 are positioned adjacent to and physically touching corresponding contact pads 2 on the top surface of connector base 1. In step 108, connector base 1 is heated so that the small menisci of solidified solder 3c liquify again and a portion thereof runs onto the corresponding contact pads 2. In step 109, connector base 1 is cooled or allowed to cool so that the small menisci of now liquified solder 3c solidify again as well as the portions thereof on the corresponding contact pads 2, thereby forming both a mechanical and electrical connection between the lotus spring contacts 3 and the corresponding contact pads 2. Note that, where organic film 4 comprises a temporarily retained organic film and contact pads 2 have a meniscus of solder thereon, steps 105 and 106 may be omitted because the solder on the contact pads 2 is sufficient to form an adequate electrical and mechanical connection between lotus spring contacts 3 and the corresponding contact pads 2.

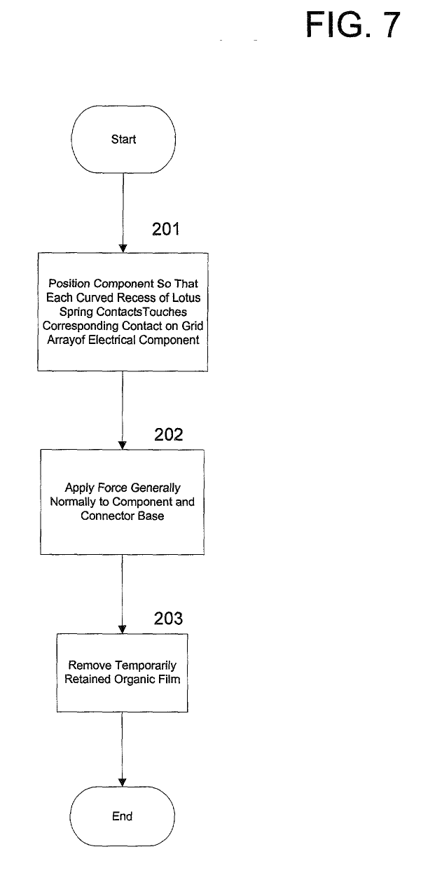

Referring now to FIG. 7, a flow diagram of a method for connecting an electrical component 5 having a grid array of electrical contacts (e.g., BGA 6 or LGA 7) disposed on at least one side thereof to connector 10 is depicted. In step 201 the electrical component is positioned so that the curved recess (e.g., 6e) at the open end of each of the locust spring contacts 3 touches a corresponding electrical contact on the grid array of component 5. In step 202, a force is applied generally normal to component 5 and connector base 1 so that each of the lotus spring contacts 3 engage the corresponding contacts on the grid array of electrical contacts, thereby creating a physical and electrical connection between connector 10 and electric component 5. Where organic film 4 comprises a temporarily retained organic film, optional step 203 comprises removing the temporarily retained organic film. Depending on the type of temporarily retained organic film used, it may be removed by washing connector 10 with a solvent such as hot water and/or alcohol or the like.

While the invention has been described in connection with the certain embodiments depicted in the various figures, it is to be understood that other similar embodiments may be used or modifications and additions may be made to the described embodiments for performing the same function of the invention without deviating therefrom. Therefore, the invention should not be limited to any single embodiment, but rather construed in breadth and scope in accordance with the recitation of the appended claims.

We claim:

1. An electrical connector comprising:
a plurality of lotus spring contacts, each lotus spring contact having at least two beams, each beam having a base and distal end, the beams of each lotus spring contact being joined at the base ends thereof to form a base for being connected to a connector base, the beams of each lotus spring contact defining a recess at the distal ends thereof for receiving a corresponding contact of a grid array; and
a generally planar organic film oriented substantially perpendicular to the plurality of lotus spring contacts such that the lotus spring contacts protrude therethrough; wherein the organic fihn provides structural integrity to the beams of the lotus spring contacts.

2. The connector of claim 1, wherein the lotus spring contacts protrude through the organic film such that the flhn is located adjacent the base ends of the lotus spring contacts.

3. The connector of claim 1, wherein each lotus spring contact is constructed from a high thermally and electrically conductive metal.

4. The connector of claim 1, wherein the lotus spring contacts are nickel plated and finished with gold.

5. The connector of claim 1, wherein the organic film is a permanently retained organic film.

6. The connector of claim 5, wherein the organic film is a KAPTON film.

7. The connector of claim 1, wherein the organic film is about 0.001 inches thick.

8. The connector of claim 1, wherein the organic film is a temporarily retained film.

9. The connector of claim 8, wherein the organic film is gelatin deposited on a thin polymer film.

10. The connector of claim 1, wherein the organic film is constructed from a member of the group consisting of polyimide and polyester.

11. The connector of claim 1, wherein the base of each lotus spring contact has a meniscus of solder therein.

12. A connector comprising:
a connector base having a plurality of electrically conductive pads disposed on a first surface thereof;
a plurality of lotus spring contacts, each lotus spring contact having at least two beams, each beam having a base and distal end, the beams of each lotus spring contact being joined at the base ends thereof to form a base, the base of each lotus spring contact being electrically and mechanically connected to the electrically conductive pads, the beams of each lotus spring contact defining a recess at the distal ends thereof for receiving a corresponding contact of a grid array; and
a generally planar organic film oriented substantially perpendicular to the lotus spring contacts such that the lotus spring contacts protrude therethrough; wherein the organic film provides structural integrity to the beams of the lotus spring contacts.

13. The connector of claim 12, wherein the lotus spring contacts protrude through the organic film such that the film is located adjacent the base ends of the lotus spring contacts.

14. The connector of claim 12, wherein the lotus spring contacts is constructed from a high thermally and electrically conductive metal.

15. The connector of claim 12, wherein the lotus spring contacts are nickel plated and finished with gold.

16. The connector of claim 12, wherein the organic film is a permanently retained organic film.

17. The connector of claim 16, wherein the organic film is a KAPTON film.

18. The connector of claim 12, wherein the organic film is about 0.001 inches thick.

19. The connector of claim 12, wherein the organic film is a temporarily retained organic film.

20. The connector of claim 19, wherein the organic film is gelatin deposited on a thin polymer film.

21. The connector of claim 12, wherein the organic film is constructed from a member of the group consisting of polyimide and polyester.

22. The connector of claim 12, wherein the connector base comprises a non-conducting material.

23. The connector of claim 22, wherein the non-conducting material is any member of the group consisting of alumina, epoxy resin, boron nitride, and aluminum nitride.

24. The connector of claim 12, wherein the connector base is a heat sink covered with a non-conducting material.

25. The connector of claim 12, further comprising a heat sink in thermal communication with the connector base.

26. A method of using an electrical connector, the electrical connector comprising a connector base mechanically and electrically connected to a plurality of lotus spring contacts, each of the lotus spring contacts having a plurality of beams, the beams having a base and distal end, the distal ends of each lotus spring contact defining a recess for receiving a corresponding electrical contact on an electrical component, and a generally planar organic film oriented substantially perpendicular to the lotus spring contacts such that each of the lotus spring contacts protrude therethrough, comprising
positioning the electrical component so that the curved recess of each lotus spring contact touches the corresponding electrical contact on the electrical component; and
applying a force generally normally to the component and connector base so that each of the lotus spring contacts engage the corresponding electrical contact on the component.

27. The method of claim 26, further comprising:
removing the organic film.

28. The method of claim 26, further comprising removing the organic film by washing the connector with a solvent.

29. A method of assembling an electrical connector comprising:
forming a plurality of lotus spring contacts, each lotus spring contact having at least two beams, each beam having a base and distal end, the beams of each lotus spring contact being joined at the base ends thereof to form a base, the beams of each lotus spring defining a recess at the distal ends thereof;
positioning the lotus spring contacts in a grid array;
forming an organic film around the lotus spring contacts;
forming a meniscus of liquid solder between the beams of each of the lotus spring contacts adjacent the base ends thereof;
allowing each of the meniscus of liquid solder to solidify;
positioning the base of each of the lotus spring contacts adjacent to and touching a corresponding contact pad on a surface of a connector base;
heating the connector base so that each of the meniscus of solder liquify and a portion thereof runs onto the corresponding contact pad;
allowing each meniscus of solder and each portion thereof on the corresponding contact pad to solidify.

30. The method of claim 29, wherein the step of forming the organic film comprises:
positioning an organic film above the lotus spring contacts so that the distal end of each of the lotus spring contacts touches a surface of the film; and
applying a force generally normally to the organic film so that the distal end of each of the lotus spring contacts puncture and protrude through the film.
